(19) United States
(12) Patent Application Publication
(10) Pub. No.: US 2013/0015918 A1
(43) Pub. Date: Jan. 17, 2013

(54) HIGH SPEED AMPLIFIER

(71) Applicants: Victoria L. Wang Limketkai, Dallas, TX (US); Venkatesh Srinivasan, Dallas, TX (US)

(72) Inventors: Victoria L. Wang Limketkai, Dallas, TX (US); Venkatesh Srinivasan, Dallas, TX (US)

(73) Assignee: Texas Instruments Incorporated, Dallas, TX (US)

(21) Appl. No.: 13/184,131

(22) Filed: Jul. 15, 2011

(51) Int. Cl. H03F 3/45

(52) U.S. Cl. 330/253

(57) ABSTRACT

For high speed amplifiers, the parasitic capacitances between a differential input pairs and a cascoded bias network can introduce a pole that can affect performance. Here, a feedforward network has been provided that compensates for this pole by introducing a zero that effectively cancels the pole, moving the next parasitic without any additional power. This is generally accomplished by using a pair of feedforward capacitors coupled across the transistors of the cascoded bias network, which reduced power consumption.

### TECHNICAL FIELD

The invention relates generally to high speed amplifiers and, more particularly, to a high speed telescopic amplifier.

### BACKGROUND

Turning to FIG. 1, a conventional telescopic amplifier 100 can be seen. As shown, this telescopic amplifier 100 generally comprises a differential input pair (which generally comprises transistors Q2 and Q7) and several bias networks (which generally comprise cascoded transistor pairs Q1/Q6, Q3/Q8, Q4/Q9, and Q5/Q10). These bias networks are typically configured as current minors (each being coupled to a diode-connected transistor) or may be configured so that biases BIAS1 to BIAS4 are bias voltages. Generally, for high speed applications (i.e., greater than 10 GHz), parasitics (such as parasitic capacitances) can become problematic. In particular, parasitic capacitances resulting from configuration of transistors Q1 to Q4 and Q6 to Q9 can cause signal degradation.

Looking first to the internal nodes between transistors Q1 to Q3 and Q6 to Q8, bias network Q3/Q8 and differential pair Q2/Q7 introduce a parasitic pole (which is typically at a ratio of transconductance to parasitic capacitance CP). The parasitic capacitance CP is generally a linear combination of the gate-drain, source-body, and gate-source capacitances of transistors Q2, Q3, Q7 and Q8 (represented by parasitic capacitors CP1 to CP6 for the sake of simplicity). Typically, with a current of 1 mA in each branch, a transconductance of 10 mS, and a total parasitic capacitance of 450 fF, there is a pole at 3.5 GHz, and, with a current of 600 μA in each branch, a transconductance of 6 mS, and, because there is a total parasitic capacitance of 450 fF, there is a pole at 2.1 GHz. This parasitic capacitance is usually large due to a low input referred noise limitation imposed on the amplifier 100. Thus, there is a need to compensate for the pole introduced by the parasitic capacitance of bias network Q3/Q8 and differential pair Q2/Q7.

Turning to the input terminals INP and INM, each of the transistors Q2 and Q7 has a gate-drain parasitic capacitance (represented by parasitic capacitors CP1 and CP3). These gate-drain parasitic capacitances CP1 and CP3 result in a right-half plane zero, which can be at (for example) about 20 GHz (i.e., g_{mdiff}/CP). Thus, there is a need to compensate for the zero introduced by the parasitic capacitance of the differential input pair Q2/Q7.

An example of a conventional circuit is U.S. Patent Pre-Grant Publ. Non. 2002/0024382.

### SUMMARY

In accordance with an embodiment of the present invention, an apparatus is provided. The apparatus comprises an amplifier that receives an input signal and that generates an output signal, wherein the amplifier includes: a differential input pair that receives the input signal; a first transistor having a first passive electrode, a second passive electrode, and a control electrode, wherein the first passive electrode of the first transistor is coupled to the differential pair; and a second transistor having a first passive electrode, a second passive electrode, and a control electrode, wherein the control electrode of the second transistor is coupled to the control electrode of the first transistor, and wherein the first passive electrode of the second transistor is coupled to the differential input pair; and a feedforward network having: a first feedforward capacitor that is coupled between the first and second passive electrodes of the first transistor; and a second feedforward capacitor that is coupled between the first and second passive electrodes of the second transistor.

In accordance with an embodiment of the present invention, the amplifier further comprises: a first output terminal that is coupled to the second passive electrode of the first transistor; a second output terminal that is coupled to the second passive electrode of the second transistor; and a bias network that is coupled to differential input pair.

In accordance with an embodiment of the present invention, the first and second transistors are MOS transistors, and wherein the first passive electrode, the second passive electrode, and the control electrode of each of the first and second transistors are the source, drain, and gate, respectively.

In accordance with an embodiment of the present invention, the first and second transistors further comprise first and second PMOS transistors, respectively.

In accordance with an embodiment of the present invention, the differential input pair further comprises: a third PMOS transistor that is coupled to the source of the first PMOS transistor at its drain and that receives a first portion of the input signal at its gate; and a fourth PMOS transistor that is coupled to the source of the second PMOS transistor at is drain and that receives a second portion of the input signal at its gate.

In accordance with an embodiment of the present invention, the bias network further comprises: a fifth PMOS transistor that is coupled to the source of the third PMOS transistor at its drain; and a sixth PMOS transistor that is coupled to the source of the fourth PMOS transistor at is drain and that is coupled to the gate of the fifth PMOS transistor at its gate.

In accordance with an embodiment of the present invention, the first and second feedforward capacitors further comprise first and second metal-insulator-metal (MIM) capacitors, respectively.

In accordance with an embodiment of the present invention, the capacitance of each of the first and second MOS capacitors is about 3 pF.

In accordance with an embodiment of the present invention, an apparatus is provided. The apparatus comprises a first output terminal; a second output terminal; a first PMOS transistor; a second PMOS transistor that is coupled to the first PMOS transistor at its gate, wherein the first and second PMOS transistors receive a first bias at their gates; a third PMOS transistor that is coupled to the drain of the first PMOS transistor at its source and that receives a first portion of a differential input signal at its gate; a fourth PMOS transistor that is coupled to the drain of the second PMOS transistor at its source and that receives a second portion of the differential input signal at its gate; a fifth PMOS transistor that is coupled to the drain of the third PMOS transistor at its source and the first output terminal at its drain; a sixth PMOS transistor that is coupled to the drain of the fourth PMOS transistor at its source, the second output terminal at its drain, and the gate of the fifth PMOS transistor at its gate, wherein the fifth and sixth PMOS transistors receive a second bias at their gates; a first NMOS transistor that is coupled to the drain of the fifth PMOS transistor at its drain; a second NMOS transistor that is coupled to the drain of the sixth NMOS transistor at its drain and the gate of the first NMOS transistor at its gate, wherein the first and second NMOS transistors receive a third bias at their gates; a first feedforward capacitor that is coupled between the drain and source of the fifth PMOS transistor; and a second feedforward capacitor that is coupled between the drain and source of the sixth PMOS transistor.

In accordance with an embodiment of the present invention, the first and second feedforward capacitors further comprise first and second MIM capacitors, respectively.

In accordance with an embodiment of the present invention, the capacitance of each of the first and second MIM capacitors is about 3 pF.

In accordance with an embodiment of the present invention, an apparatus is provided. The apparatus comprises a first output terminal; a second output terminal; a first PNP transistor; a second PNP transistor that is coupled to the first PNP transistor at its base, wherein the first and second PNP transistors receive a first bias at their bases; a third PNP transistor that is coupled to the collector of the first PNP transistor at its emitter and that receives a first portion of a differential input signal at its base; a fourth PNP transistor that is coupled to the collector of the second PNP transistor at its emitter and that receives a second portion of the differential input signal at its base; a fifth PNP transistor that is coupled to the collector of the third PNP transistor at its emitter and the first output terminal at its collector; a sixth PNP transistor that is coupled to the collector of the fourth PNP transistor at its emitter, the second output terminal at its collector, and the base of the fifth PNP transistor at its base, wherein the fifth and sixth PNP transistors receive a second bias at their bases; a first NPN transistor that is coupled to the collector of the fifth PNP transistor at its collector; a second NPN transistor that is coupled to the collector of the sixth NPN transistor at its collector and the base of the first NPN transistor at its base, wherein the first and second NPN transistors receive a third bias at their bases; a first feedforward capacitor that is coupled between the emitter and collector of the fifth PNP transistor; and a second feedforward capacitor that is coupled between the emitter and collector of the sixth PNP transistor.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is an example of a conventional telescopic amplifier;

FIGS. 2A and 2B is an example of an amplifier in accordance with an embodiment of the present invention; and

FIGS. 3-4 are diagrams illustrating the use of the feedforward network in the telescopic amplifier of FIG. 2

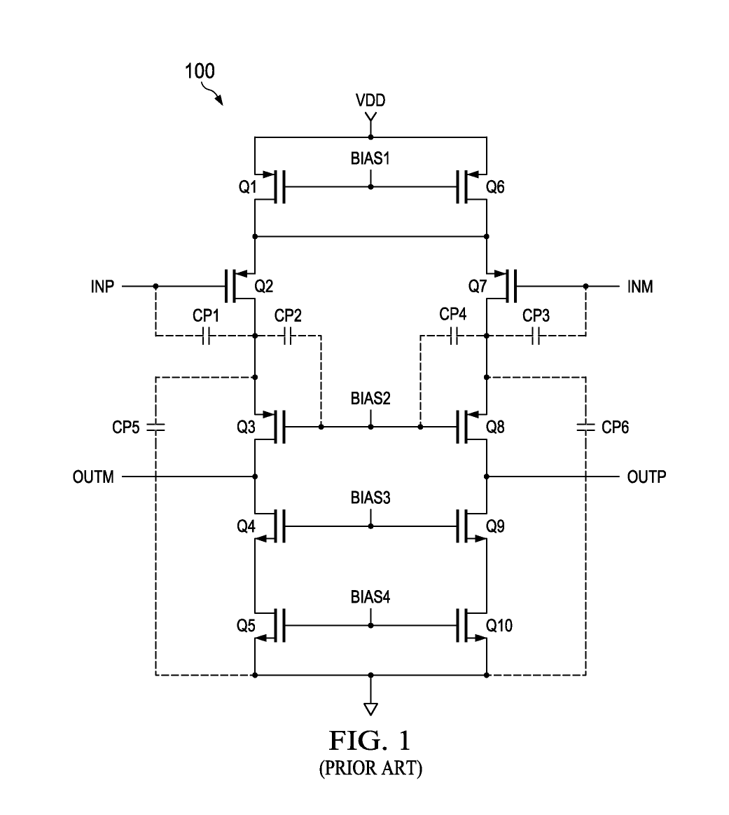

### DETAILED DESCRIPTION

Refer now to the drawings wherein depicted elements are, for the sake of clarity, not necessarily shown to scale and wherein like or similar elements are designated by the same reference numeral through the several views.

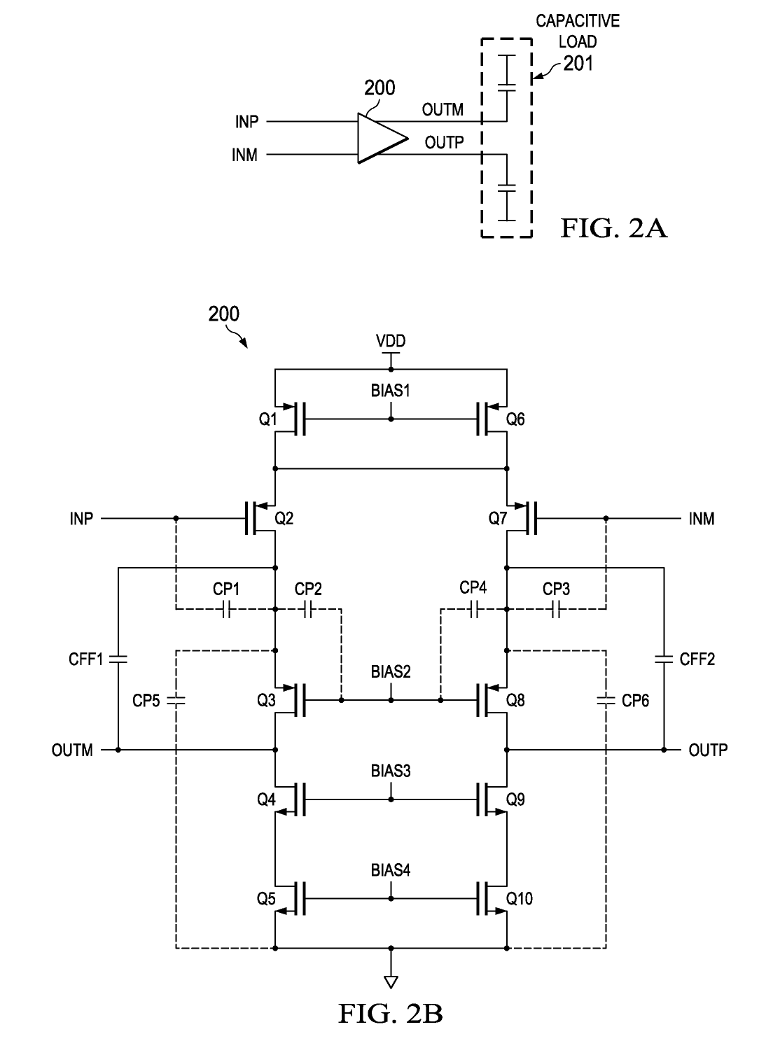

Turning to FIGS. 2A and 2B, a telescopic amplifier 200 in accordance with an embodiment of the present invention can be seen. Amplifier 200 is generally employed to drive a capacitive load 201, and telescopic amplifier 200 has the same general configuration as telescopic amplifier 100, except that telescopic amplifier 200 includes neutralization network (capacitors CN1 and CN2) and a feedforward network (capacitors CFF1 and CFF2). As shown, telescopic amplifier 200 can be implemented with MOS transistors (i.e., transistors Q1 to Q3 and Q6 to Q8 are PMOS transistors and transistors Q4, Q5, Q9, and Q10 are NMOS transistors), but telescopic amplifier 200 can also be implemented with bipolar transistors (i.e., transistors Q1 to Q3 and Q6 to Q8 are PNP transistors and transistors Q4, Q5, Q9, and Q10 are NPN transistors). The feedforward network (capacitors CFF1 and CFF2) are generally employed to improve performance by compensating for poles and zeros, while also reducing power consumption. Alternatively, transistors Q1 to Q10 can be replaced with transistors of the opposite conductivity type than shown in FIG. 2 (i.e., transistor Q4 can be a PMOS or PNP transistor instead of an NMOS or NPN transistor while transistor Q1 can be an NMOS or NPN transistor instead of a PMOS or PNP transistor).

Looking first to the feedforward network CFF1/CFF2, these capacitors CFF1 and CFF2 effectively cancel the pole introduced by parasitic capacitances CP1 (gate-drain capacitance of transistor Q2), CP2 (gate-source capacitance of transistor Q3), CP3 (gate-drain capacitance of transistor Q7) and CP4 (gate-source capacitance of transistor Q8) with a zero. The transfer functions H_{M}(s) and H_{P}(s) for each half of the telescopic amplifier 100 without a neutralization network CN1/CN2 or feedforward network CFF1/CFF2 can be expressed as:

$$\begin{matrix}{H}_{M} ( s ) = \frac{A ( 1 - s \frac{CP 1}{{g}_{mQ 2}} )}{( 1 + s * WPD ) ( 1 + s \frac{CP 1 + CP 2 + CP 5}{{g}_{mQ 3}} )} , and & ( 1 ) \\ {H}_{P} ( s ) = \frac{A ( 1 - s \frac{CP 3}{{g}_{mQ 7}} )}{( 1 + s * WPD ) ( 1 + s \frac{CP 3 + CP 4 + CP 6}{{g}_{mQ 8}} )} , & ( 2 )\end{matrix}$$

where WPD is the dominant pole due to the load at the output terminals OUTP and OUTM, g_{mQ2}, g_{mQ3}, g_{mQ7}, and g_{mQ8} are the transconductances of the transistors Q2, Q3 Q7, and Q8, respectively, As can be seen from equations (1) and (2), the transfer functions H_{M}(s) and H_{P}(s) indicates a dominant pole WPD, parasitic poles at

$$\frac{{g}_{m Q 3}}{CP 1 + CP 2 + CP 5} and \frac{{g}_{m Q 8}}{CP 3 + CP 4 + CP 6} ,$$

and a right-half plane zeros at

$$\frac{{g}_{m Q 2}}{CP 1} and \frac{{g}_{mQ 7}}{CP 3} .$$

To compensate for the parasitic poles

$$\frac{{g}_{mQ 3}}{CP 1 + CP 2 + CP 5} and \frac{{g}_{mQ 8}}{CP 3 + CP 4 + CP 6} ,$$

capacitors CFF1 and CFF2 are respectively coupled between the source and drain of transistors Q3 and Q8, respectively, of the bias network, which is casocoded with differential input pair Q2/Q7. The capacitors CFF1 and CFF2 (which can be metal-insulator-metal (MIM) capacitors so as to have high linearity or can be MOS capacitors) introduce a left-half plane zero (which is generally at gₘ/CFF). Namely, the feedforward network CFF1/CFF2 modify transfer functions H_{M}(s) and H_{P}(s) (shown in equations (1) and (2)) as follows:

$$\begin{matrix}{H}_{M} ( s ) = \frac{A ( 1 - s \frac{CP 1}{{g}_{mQ 2}} ) ( 1 + s \frac{CFF 1}{{g}_{mQ 3}} )}{( 1 + s * WPD ) ( 1 + s \frac{CP 1 + CP 2 + CP 5 + CFF 1}{{g}_{mQ 3}} )} , and & ( 3 ) \\ {H}_{P} ( s ) = \frac{A ( 1 - s \frac{CP 3}{{g}_{m Q 7}} ) ( 1 + s \frac{CFF 2}{{g}_{m Q 8}} )}{( 1 + s * WPD ) ( 1 + s \frac{CP 3 + CP 4 + CP 6 + CFF 2}{{g}_{mQ 8}} )} . & ( 4 )\end{matrix}$$

As shown in equations (3) and (4), the capacitance introduced by the feedforward network CFF1/CFF2 modifies the location of the parasitic poles from

$$\frac{{g}_{mQ 3}}{CP 1 + CP 2 + CP 5} and \frac{{g}_{mQ 8}}{CP 3 + CP 4 + CP 6} to$$

$$\frac{{g}_{mQ 3}}{CP 1 + CP 2 + CP 5 + CFF 1} and \frac{{g}_{mQ 8}}{CP 3 + CP 4 + CP 6 + CFF 2}$$

while simultaneously introducing a left-half plane zeros at

$$\frac{{g}_{mQ 3}}{CFF 1} and \frac{{g}_{mQ 8}}{CFF 2} .$$

Thus, it the value of the capacitance of the feedforward network CFF1/CFF2 is much greater than the parasitic capacitances (i.e., CFF1>>(CP1+CP2+CP5) and CFF2>>(CP3+CP4+CP6)), then the then the feedforward network CFF1/CFF2 enables the left-half plane zeros (effectively) to cancel out the parasitic poles because:

$$\begin{matrix}\begin{matrix}{H}_{M} ( s ) = \frac{A ( 1 - s \frac{ CP 1}{{g}_{mQ 2}} ) ( 1 + s \frac{CFF 1}{{g}_{mQ 3}} )}{( 1 + s * WPD ) ( 1 + s \frac{CP 1 + CP 2 + CP 5 + CFF 1}{{g}_{mQ 3}} )} \\ \approx \frac{A ( 1 - s \frac{CP 1}{{g}_{mQ 2}} ) ( 1 + s \frac{CFF 1}{{g}_{mQ 3}} )}{( 1 + s * WPD ) ( 1 + s \frac{CFF 1}{{g}_{mQ 3}} )} \\ = \frac{A ( 1 - s \frac{CP 1}{{g}_{m Q 2}} )}{( 1 + s * WPD )} ,\end{matrix} & ( 5 ) \\ and & \\ \begin{matrix}{H}_{P} ( s ) = \frac{A ( 1 - s \frac{CP 3}{{g}_{mQ 7}} ) ( 1 + s \frac{CFF 2}{{g}_{mQ 8}} )}{( 1 + s * WPD ) ( 1 + s \frac{CP 3 + CP 4 ++ CP 6 + CFF 2}{{g}_{mQ 8}} )} \\ \approx \frac{A ( 1 - s \frac{CP 3}{{g}_{mQ 7}} ) ( 1 + s \frac{CFF 2}{{g}_{mQ 8}} )}{( 1 + s * WPD ) ( 1 + s \frac{ CFF 2}{{g}_{mQ 8}} )} \\ = \frac{A ( 1 - s \frac{CP 3}{{g}_{mQ 7}} )}{( 1 + s * WPD )} .\end{matrix} & ( 6 )\end{matrix}$$

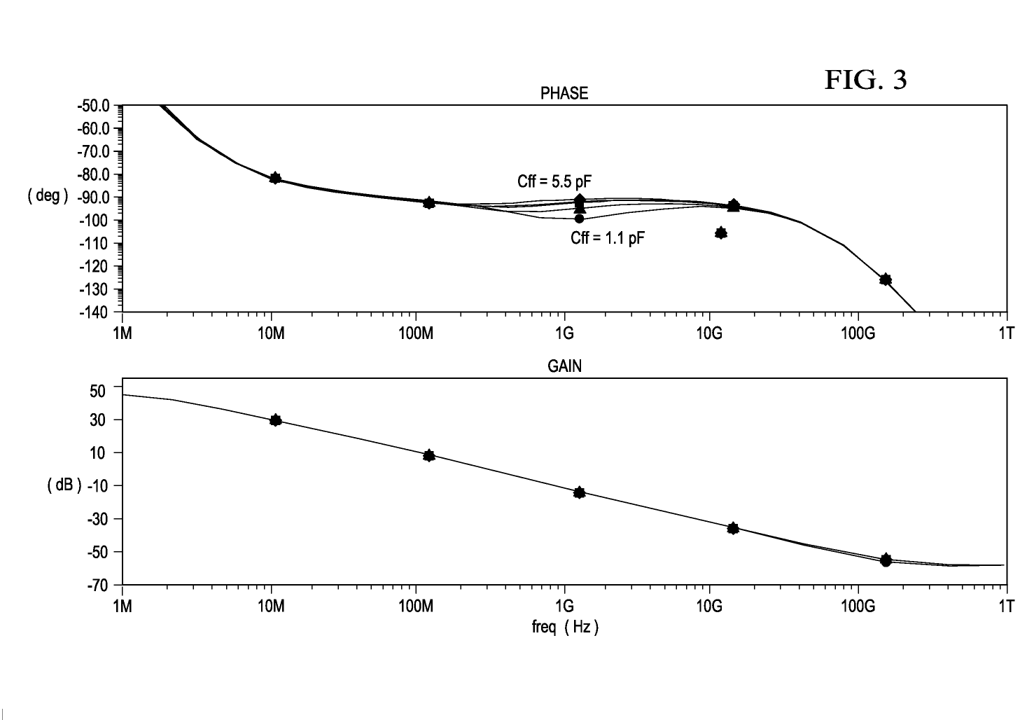

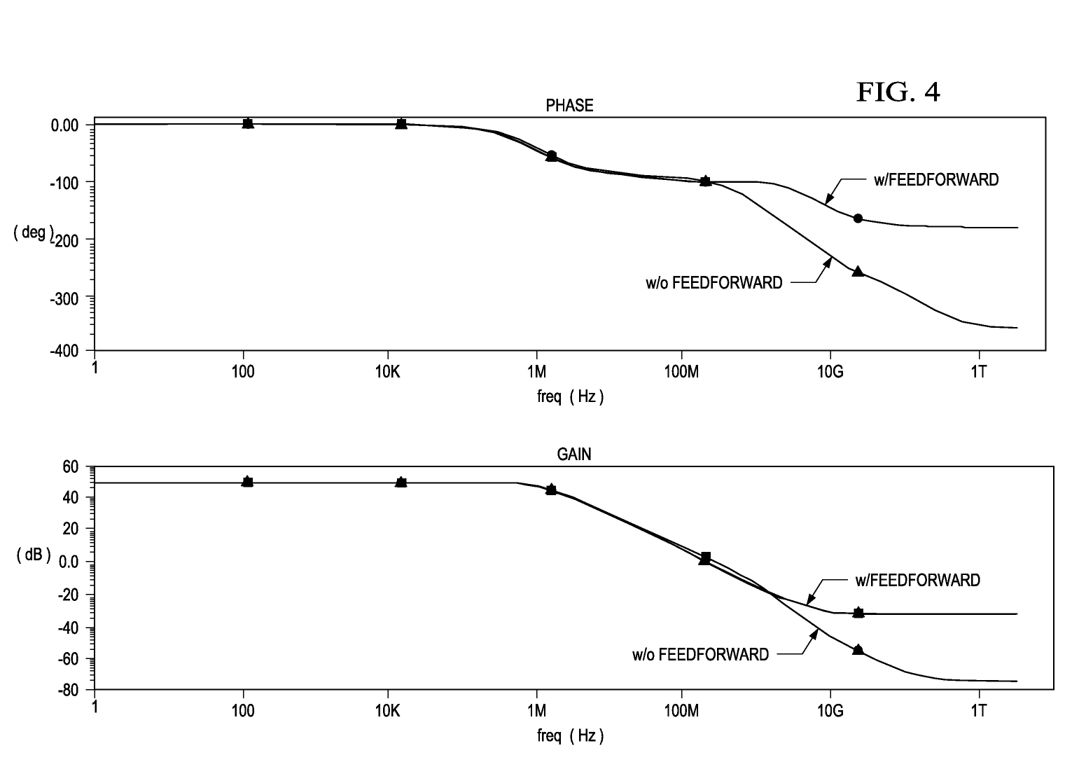

As an example, for a transconductance of 10 mS, a parasitic capacitance of 450 fF, and a feedforward capacitance of 3 pF, there is a zero is created at 525 MHz, and the parasitic pole is moved from 3.5 GHz to 461 MHz. In FIG. 3, the phase and gain can be seen as the feedforward capacitance is swept between 1.0 pF and 5.5 pF, and, as shown, the choice of 3 pF would result in the best solution so as to effectively cancel the pole introduced by parasitic capacitances CP1 to CP4, while attempting to minimize area used for the feedforward network CFF1/CFF2. Additionally, in FIG. 4, the phase and gain of the telescopic amplifier 200 can be seen with and without the feedforward network CFF1/CFF2.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
an amplifier that is configured to receive an input signal and that is configured to generate an output signal, wherein the amplifier includes:
a differential input pair having:
a first PMOS transistor that is configured to receive a first portion of the input signal at its gate; and
a second PMOS transistor that is configured to receive a second portion of the input signal at its gate;
a third PMOS transistor that is coupled to the drain of the first PMOS transistor at its source; and
a fourth PMOS transistor that is coupled to the gate of the third PMOS transistor at its gate and that is coupled to the drain of the second PMOS transistor at its source;
a feedforward network having:
a first feedforward capacitor that is coupled between the drain and source of the third PMOS transistor; and
a second feedforward capacitor that is coupled between the drain and source of the fourth PMOS transistor;
a first output terminal at the drain of the third PMOS transistor; and
a second output terminal at the drain of the fourth PMOS transistor.

2. The apparatus of claim 1, wherein the amplifier further comprises a bias network that is coupled to differential input pair.

3-5. (canceled)

6. The apparatus of claim 5, wherein the bias network further comprises:
a fifth PMOS transistor that is coupled to the source of the first PMOS transistor at its drain; and
a sixth PMOS transistor that is coupled to the source of the second PMOS transistor at is drain and that is coupled to the gate of the fifth PMOS transistor at its gate.

7-8. (canceled)

9. The apparatus of claim 1, wherein the first and second feedforward capacitors further comprise first and second metal-insulator-metal (MIM) capacitors, respectively.

10. The apparatus of claim 9, wherein the capacitance of each of the first and second MIM capacitors is about 3 pF.

11. An apparatus comprising:
a first output terminal;
a second output terminal;
a first PMOS transistor;
a second PMOS transistor that is coupled to the first PMOS transistor at its gate, wherein the first and second PMOS transistors are configured to receive a first bias at their gates;
a third PMOS transistor that is coupled to the drain of the first PMOS transistor at its source and that is configured to receive a first portion of a differential input signal at its gate;
a fourth PMOS transistor that is coupled to the drain of the second PMOS transistor at its source and that is configured to receive a second portion of the differential input signal at its gate;
a fifth PMOS transistor that is coupled to the drain of the third PMOS transistor at its source and the first output terminal at its drain;
a sixth PMOS transistor that is coupled to the drain of the fourth PMOS transistor at its source, the second output terminal at its drain, and the gate of the fifth PMOS transistor at its gate, wherein the fifth and sixth PMOS transistors are configured to receive a second bias at their gates;
a first NMOS transistor that is coupled to the drain of the fifth PMOS transistor at its drain;
a second NMOS transistor that is coupled to the drain of the sixth NMOS transistor at its drain and the gate of the first NMOS transistor at its gate, wherein the first and second NMOS transistors are configured to receive a third bias at their gates;
a first feedforward capacitor that is coupled between the drain and source of the fifth PMOS transistor; and
a second feedforward capacitor that is coupled between the drain and source of the sixth PMOS transistor.

12. The apparatus of claim 11, wherein the first and second feedforward capacitors further comprise first and second MIM capacitors, respectively.

13. The apparatus of claim 12, wherein the capacitance of each of the first and second MIM capacitors is about 3 pF.

14. An apparatus comprising:
a first output terminal;
a second output terminal;
a first PNP transistor;
a second PNP transistor that is coupled to the first PNP transistor at its base, wherein the first and second PNP transistors are configured to receive a first bias at their bases;
a third PNP transistor that is coupled to the collector of the first PNP transistor at its emitter and that is configured to receive a first portion of a differential input signal at its base;
a fourth PNP transistor that is coupled to the collector of the second PNP transistor at its emitter and that is configured to receive a second portion of the differential input signal at its base;
a fifth PNP transistor that is coupled to the collector of the third PNP transistor at its emitter and the first output terminal at its collector;
a sixth PNP transistor that is coupled to the collector of the fourth PNP transistor at its emitter, the second output terminal at its collector, and the base of the fifth PNP transistor at its base, wherein the fifth and sixth PNP transistors are configured to receive a second bias at their bases;
a first NPN transistor that is coupled to the collector of the fifth PNP transistor at its collector;
a second NPN transistor that is coupled to the collector of the sixth NPN transistor at its collector and the base of the first NPN transistor at its base, wherein the first and second NPN transistors are configured to receive a third bias at their bases;
a first feedforward capacitor that is coupled between the emitter and collector of the fifth PNP transistor; and
a second feedforward capacitor that is coupled between the emitter and collector of the sixth PNP transistor.

15. The apparatus of claim 14, wherein the first and second feedforward capacitors further comprise first and second MIM capacitors, respectively.

16. The apparatus of claim 15, wherein the capacitance of each of the first and second MIM capacitors is about 3 pF.

17. An apparatus comprising:
an amplifier that is configured to receive an input signal and that is configured to generate an output signal, wherein the amplifier includes:
a differential input pair having:
a first PNP transistor that is configured to receive a first portion of the input signal at its base; and
a second PNP transistor that is configured to receive a second portion of the input signal at its base;
a third PNP transistor that is coupled to the collector of the first PNP transistor at its emitter; and
a fourth PNP transistor that is coupled to the base of the third PNP transistor at its base and that is coupled to the collector of the second PNP transistor at its emitter;
a feedforward network having:
a first feedforward capacitor that is coupled between the emitter and collector of the third PNP transistor; and
a second feedforward capacitor that is coupled between the emitter and collector of the fourth PNP transistor;
a first output terminal at the collector of the third PNP transistor; and
a second output terminal at the collector of the fourth PNP transistor.

18. The apparatus of claim 17, wherein the amplifier further comprises a bias network that is coupled to differential input pair.

19. The apparatus of claim 18, wherein the bias network further comprises:
a fifth PNP transistor that is coupled to the emitter of the first PNP transistor at its drain; and
a sixth PNP transistor that is coupled to the emitter of the second PNP transistor at is collector and that is coupled to the base of the fifth PNP transistor at its base.

20. The apparatus of claim 17, wherein the first and second feedforward capacitors further comprise first and second MIM capacitors, respectively.

21. The apparatus of claim 20, wherein the capacitance of each of the first and second MIM capacitors is about 3 pF.
